(19) United States
(12) Patent Application Publication
(10) Pub. No.: US 2021/0202268 A1
(43) Pub. Date: Jul. 1, 2021

(54) PACKAGE DEVICE AND MANUFACTURING METHOD THEREOF

(71) Applicant: POWERTECH TECHNOLOGY INC., Hsinchu County (TW)

(72) Inventors: Nan-Chun Lin, HSINCHU COUNTY (TW); Hung-Hsin Hsu, HSINCHU COUNTY (TW); Shang-Yu Chang Chien, HSINCHU COUNTY (TW)

(21) Appl. No.: 17/124,448

(22) Filed: Dec. 16, 2020

Related U.S. Application Data
(60) Provisional application No. 62/955,456, filed on Dec. 31, 2019.

(30) Foreign Application Priority Data
Aug. 3, 2020 (TW) 109126169

(51) Int. Cl. H01L 21/48; H01L 21/56; H01L 23/538; H01L 23/31

(52) U.S. Cl. CPC H01L 21/4853; H01L 21/4857; H01L 23/3128; H01L 23/5383; H01L 21/56

(57) ABSTRACT

A package device and a manufacturing method thereof are provided. The manufacturing method of the package device includes providing a substrate and forming a redistribution layer on the substrate. The substrate has at least one device region and a non-device region. The redistribution layer includes at least one inspection structure and at least one wire structure. The wire structure is disposed in the device region, a part of the inspection structure and a part of the wire structure are formed of a same layer, and the inspection structure has a trench exposing the part of the inspection structure.

### CROSS REFERENCE TO RELATED APPLICATIONS

This patent application claims the benefit of U.S. provisional application No. 62/955,456, filed Dec. 31, 2019 and the benefit of Taiwan patent application No. 109126169 filed Aug. 3, 2020, and the entire contents of which are incorporated herein by reference.

### BACKGROUND OF THE INVENTION

### 1. Field of the Invention

The present invention relates to a package device and a manufacturing method thereof, and more particularly to a package device with an inspection block for in-line monitoring and a manufacturing method thereof.

### 2. Description of the Prior Art

Due to the requirements for portability and multi-function of consumer electronic products, the development of electronic packaging technology is forced towards small size, high performance and cost reduction. Recently, the common packaging technology is to dispose a plurality of unpackaged chips on a large carrier, form an encapsulant around the chips, and then form a redistribution layer on the chips before cutting, so that the input/output contacts of the chips with higher density may be electrically connected to solder balls with lower density through the redistribution layer. Thereafter, the semi-finished products including the chips, the encapsulant and the redistribution layer are cut into a plurality of package devices.

However, the machine error or fatigue and the change of the process conditions exist in the processes, and a correlation exists between the process conditions and the chip positions. As a result, package devices that do not meet the standards or have inconsistent performance are manufactured. The package device can be cut by the focus ion beam (FIB), so as to analyze the internal structure of the package device to find out the factors that do not meet the standards or are inconsistent. Nevertheless, this method needs to cut the semi-finished product that is still being manufactured to expose the film to be inspected, and then perform image analysis, which is time-consuming. Furthermore, when there are many samples to be inspected, it is easy to be limited by the number of FIB machines, thereby further affecting the production efficiency.

### SUMMARY OF THE INVENTION

One of the objectives of the present invention is to provide a package device and a manufacturing method thereof to improve production efficiency and obtain accurate inspection results.

According to an embodiment, the present invention provides a manufacturing method of a package device. First, a substrate is provided, wherein the substrate has at least one device region and a non-device region. Then, a redistribution layer is formed on the substrate, wherein the redistribution layer includes at least one inspection structure and at least one wire structure, the at least one wire structure is disposed in the at least one device region, a part of the at least one inspection structure and a part of the at least one wire structure are formed of a same layer, and the at least one inspection structure has a trench exposing the part of the at least one inspection structure.

According to an embodiment, the present invention provides a package device. The package device includes a substrate and a redistribution layer disposed on the substrate. The redistribution layer includes at least one inspection structure and at least one wire structure, a part of the at least one inspection structure and a part of the at least one wire structure are formed of a same layer, and the at least one inspection structure has a trench exposing the part of the at least one inspection structure.

In the package device and the manufacturing method thereof of the present invention, through the inspection structure having the trench, there is no need to perform the FIB cutting to the semi-finished package product, and in-line inspection or monitoring may be directly performed to the structures of specific positions or different positions of the semi-finished package product. Therefore, the time for cutting the semi-finished package product may be saved, especially saving the time for cutting the semi-finished package product at different positions, and thus the production efficiency may be improved significantly. In addition, since there is no need to perform the FIB cutting, the inspection structure used for inspection will not be damaged to cause distortion by the FIB, so that the inspection results may be more accurate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a flow schematic diagram of a manufacturing method of a package device according to an embodiment of the present invention.

FIG. 2 illustrates a top view schematic diagram of a semi-finished package product before the cutting process of the present invention.

FIG. 3 illustrates a cross-sectional view schematic diagram along the cross line A-A′ of FIG. 2.

FIG. 4 illustrates a three-dimensional schematic diagram of an inspection structure according to a first embodiment of the present invention.

FIG. 5 illustrates a cross-sectional view schematic diagram of a semi-finished package product before the cutting process according to a second embodiment of the present invention.

FIG. 6 illustrates a cross-sectional view schematic diagram of a semi-finished package product before the cutting process according to a third embodiment of the present invention.

### DETAILED DESCRIPTION

The present invention may be understood by reference to the following detailed description, taken in conjunction with the drawings as described below. It is noted that, for purposes of illustrative clarity and being easily understood by the readers, various drawings of this invention show at least a portion of the package device or at least a portion of the structure in the steps of manufacturing the package device, and certain elements in various drawings may not be drawn to scale. In addition, the number and dimension of each element shown in drawings are only illustrative and are not intended to limit the scope of the present invention.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”.

It should be understood that when an element or layer is referred to as being “on” or “connected to” another element or layer, it may be directly on or directly connected to the other element or layer, or intervening elements or layers may be presented. In contrast, when an element is referred to as being “directly on” or “directly connected to” another element or layer, there are no intervening elements or layers presented.

It should be noted that the technical features in different embodiments described in the following can be replaced, recombined, or mixed with one another to constitute another embodiment without departing from the spirit of the present invention.

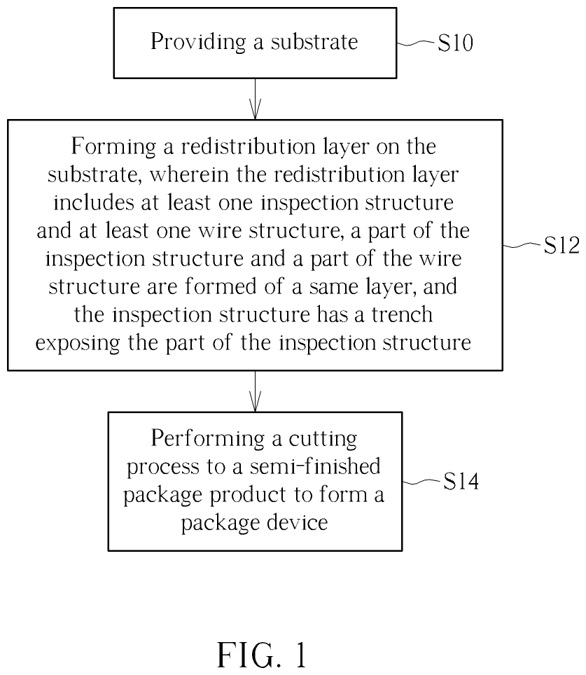

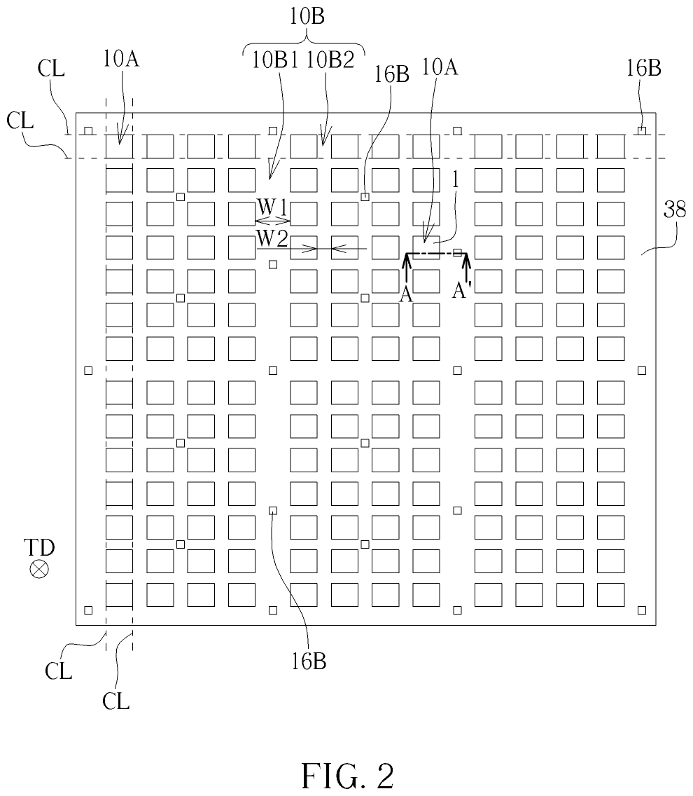

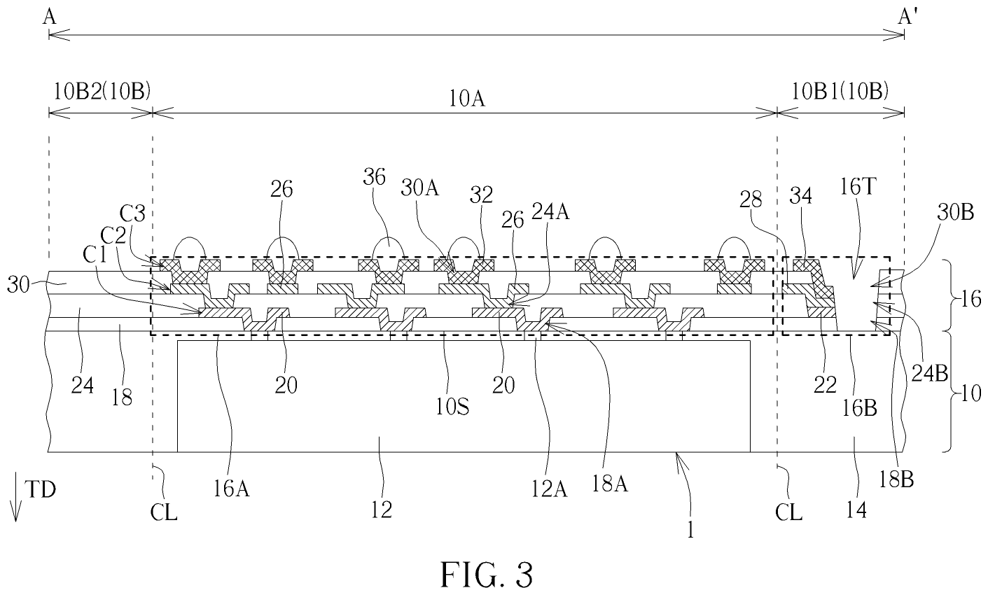

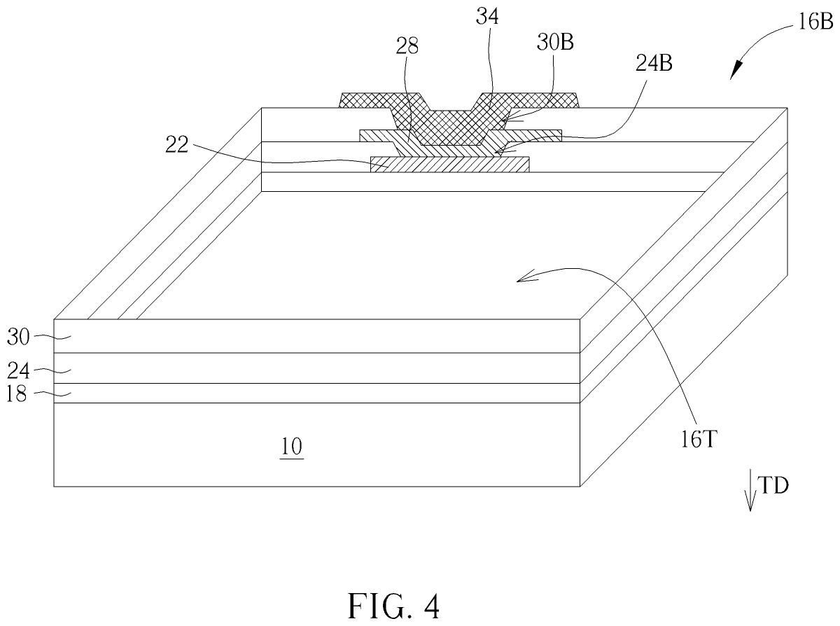

FIG. 1 illustrates a flow schematic diagram of a manufacturing method of a package device according to an embodiment of the present invention. FIG. 2 illustrates a top view schematic diagram of a semi-finished package product before the cutting process of the present invention. FIG. 3 illustrates a cross-sectional view schematic diagram along a cross line A-A′ of FIG. 2. FIG. 4 illustrates a three-dimensional schematic diagram of an inspection structure according to a first embodiment of the present invention. As shown in FIG. 1, the manufacturing method of the package device 1 may include step S10 to step S14. The manufacturing method of this embodiment will be described below with reference to FIG. 1 to FIG. 4, but not limited herein. In some embodiments, step(s) may be added or deleted according to requirements.

As shown in FIG. 1 to FIG. 3, first, the step S10 is performed. A substrate 10 is provided, and the substrate 10 may have at least one device region 10A and a non-device region 10B. In some embodiments, the non-device region 10B may include regions with different widths. For example, the non-device region 10B may include a first non-device region 10B1 and a second non-device region 10B2, and a width W1 of the first non-device region 10B1 between two adjacent device regions 10A may be greater than a width W2 of the second non-device region 10B2 between two adjacent device regions 10A, but not limited herein.

As shown in FIG. 2 and FIG. 3, in an embodiment, the substrate 10 may include at least one semiconductor chip 12 and an encapsulant 14. The semiconductor chip 12 is disposed in the device region 10A, and the encapsulant 14 may surround the semiconductor chip 12 to protect the semiconductor chip 12. The substrate 10 of this embodiment may have a plurality of device regions 10A respectively corresponding to the package devices to be formed, and a semiconductor chip 12 may be disposed in a device region 10A. In the present invention, the number of semiconductor chips 12 disposed in a single device region 10A is not limited to be one, and a stack of a plurality of semiconductor chips 12 may be disposed in the single device region 10A. The semiconductor chip 12 may be, for example, a memory chip, an application specific integrated circuit (ASIC) or other suitable semiconductor chips, but not limited herein. The encapsulant 14 may, for example, include epoxy or other suitable encapsulating materials, but not limited herein. For example, the method of forming the substrate 10 may include disposing a plurality of semiconductor chips 12 on a carrier with bonding pads 12A of the semiconductor chips facing downward (not shown in the drawings), and then forming the encapsulant 14 on the carrier and the semiconductor chips 12 to form the substrate 10. Then, the substrate 10 may be separated from the carrier, so that the bonding pads 12A of the semiconductor chips 12 may be exposed. The method of forming the substrate 10 of the present invention is not limited to the method described above. The method of forming the encapsulant 14 may, for example, include the molding process or other suitable processes, and not limited herein. The dimension of the substrate 10 may be, for example, a dimension of a panel or a wafer, and thus the process of the package device mentioned herein may be, for example, a fan-out panel-level package (FOPLP) process, a fan-out wafer-level package (FOWLP) process or a wafer-level chip-scale package (WLCSP) process, but not limited herein.

As shown in FIG. 1 and FIG. 3, after the step S10, the step S12 is performed. A redistribution layer 16 is formed on the substrate 10, and the redistribution layer 16 is electrically connected to the semiconductor chip 12. For example, after the substrate 10 is separated from the carrier, the substrate 10 may be turned upside down to make the bonding pads 12A of the semiconductor chip 12 face upward, so as to facilitate the formation of the redistribution layer 16 on the bonding pads 12A. The redistribution layer 16 may include at least one wire structure 16A and at least one inspection structure 16B, and the wire structure 16A is used for being electrically connected to the semiconductor chip 12. Since a part of the wire structure 16A and a part of the inspection structure 16B are formed of a same layer, and the inspection structure 16B has a trench 16T exposing the part of the inspection structure 16B, the inspection structure 16B may be used for monitoring or inspecting whether the wire structure 16A of the redistribution layer 16 meets the predetermined standard. For example, through the thickness, width, position and/or contour of the inspection block and the contour and/or shape of the through hole of the insulating layer exposed by the trench 16T, the structure in the wire structure 16A may be inspected or monitored, thereby further analyzing whether the formed redistribution layer 16 meets the predetermined standard. The inspection or monitoring mentioned herein may be performed by using, for example, a scanning electron microscope (SEM). In this embodiment, the inspection structure 16B is disposed in the non-device region 10B, and the wire structure 16A is disposed in the device region 10A, but not limited herein. In some embodiments, the wire structure 16A and the inspection structure 16B may be both disposed in the device region 10A.

Specifically, in the embodiment of FIG. 3, the step S12 of forming the redistribution layer 16 will be further described below. First, an insulating layer 18 is formed on the surface 10S of the substrate 10 where the bonding pads 12A are exposed, and then a through hole 18A is formed in a part of the insulating layer 18 located in the device region 10A to expose the corresponding bonding pad 12A of the semiconductor chip 12. In some embodiments, the step of forming the through hole 18A may further include forming a through hole 18B in a part of the insulating layer 18 located in the non-device region 10B to expose the substrate 10, but not limited herein. The formation of the through hole 18B may facilitate the in-line inspection or monitoring for the through hole 18B in the subsequent processes. For example, whether the top critical dimension (CD), the bottom CD and/or the position of the through hole 18B meet the standard may be inspected, and thus whether the top CD, the bottom CD and/or the position of the through hole 18A is offset and whether the width of the through hole 18A meets the standard may be further monitored. In this document, by monitoring the top CD and the bottom CD of the through hole, the situation that the through hole have undercut may be found as early as possible, so as to reduce the problem of poor quality. The step of forming the through hole 18A and the through hole 18B may include, for example, a photolithography process and an etching process or other suitable processes, but not limited herein. In some embodiments, the insulating layer 18 may not have the through hole 18B.

As shown in FIG. 3, after the through hole 18A is formed, at least one first redistribution wire 20 and at least one first inspection block 22 are formed on the insulating layer 18. The first redistribution layer 20 is in the device region 10A, and the first redistribution layer 20 may be electrically connected to the exposed bonding pad 12A of the semiconductor chip 12 through the corresponding though hole 18A. In an embodiment, the first redistribution wire 20 and the first inspection block 22 may be formed by patterning the same first conductive layer C1, and the method of patterning the first conductive layer C1 may include, for example, a photolithography process and an etching process or other suitable processes, but not limited herein. The first inspection block 22 may be, for example, separated from or connected to the first redistribution wire 20. In the embodiment of FIG. 3, the first inspection block 22 may be formed in the non-device region 10B and separated from the first redistribution wire 20, but not limited herein. When the insulating layer 18 has the through hole 18B, the first inspection block 22 may be disposed adjacent to the through hole 18B, but not limited herein. In some embodiments, the number of the first redistribution wires 20 may be plural, for example. In some embodiments, the number of the first inspection blocks 22 may be plural, for example.

As shown in FIG. 3, after the first distribution wire 10 and the first inspection block 22 are formed, another insulating layer 24 having a through hole 24A may be formed on the first redistribution wire 10, the first inspection block 22 and the insulating layer 18. The insulating layer 24 partially overlaps the first inspection block 22 in a top-view direction TD of the substrate 10. The through hole 24A is in the device region 10A and may expose the corresponding first redistribution wire 20. In some embodiments, the step of forming the through hole 24A may further include forming a through hole 24B in a part of the insulating layer 24 located in the non-device region 10B. The through hole 24B may be disposed in the non-device region 10B and expose the corresponding first inspection block 22 and the through hole 18B, so as to facilitate the in-line inspection or monitoring for the first inspection block 22 before the subsequent processes. For example, whether the width, thickness and/or position of the first inspection block 22 or the distance between the first inspection blocks 22 meet the standard may be inspected, and thus whether the first redistribution wire 20 is offset, whether the width of the first redistribution wire 20 meets the standard, or whether the distance between the first redistribution wires 20 meets the standard may be further monitored. The formation of the through hole 24B may also be helpful to in-line inspecting or monitoring whether the top CD, the bottom CD and/or the position of the through hole 24A are offset and whether the width of the through hole 24A meets the standard in subsequent processes. In some embodiments, the through hole 24B may expose the through hole 18B, so the through hole 18A may be further monitored in the subsequent processes. The step of forming the through hole 24A and the through hole 24B of the insulating layer 24 may be similar or identical to the step of forming the through hole 18A and the through hole 18B of the insulating layer 18, and will not be described redundantly.

In some embodiments, as shown in FIG. 3, the redistribution layer 16 may selectively include a plurality of conductive layers. In other words, after the insulating layer 24 is formed, at least one second redistribution wire 26 and at least one second inspection block 28 may be selectively formed on the insulating layer 24. The second redistribution wire 26 may extend to the corresponding through hole 24A and be disposed on the first redistribution wire 20 to be electrically connected to the exposed first redistribution wire 20. In an embodiment, the second redistribution wire 26 and the second inspection block 28 may be formed by patterning the same second conductive layer C2, and the method of patterning the second conductive layer C2 may include, for example, a photolithography process cooperated with an etching process or other suitable processes, but not limited herein. The second inspection block 28 may be, for example, separated from or connected to the second redistribution wire 26, but not limited herein. The second inspection block 28 may be, for example, disposed on the first inspection block 22 to facilitate the inspection for the relative relationship between the second inspection block 28 and the first inspection block 22. In some embodiments, the through hole 24B may overlap the first inspection block 22 in the top-view direction TD of the substrate 10, so that the second inspection block 28 may contact the first inspection block 22 through the through hole 24B. The top-view direction TD may be, for example, perpendicular to the surface 10S of the substrate 10. In some embodiments, the number of the second redistribution wires 26 may be plural, for example. In some embodiments, the number of the second inspection blocks 28 may be plural, for example.

As shown in FIG. 3, after the second redistribution wire 26 and the second inspection block 28 are formed, another insulating layer 30 having a through hole 30A is formed on the second redistribution wire 26, the second inspection block 28 and the insulating layer 24. The through hole 30A is in the device region 10A and may expose the corresponding second redistribution wire 26. In some embodiments, the step of forming the through hole 30A may further include forming a through hole 30B in a part of the insulating layer 30 located in the non-device region 10B. The through hole 30B may be in the non-device region 10B and expose the corresponding second inspection block 28 and the through hole 24B, so as to facilitate the in-line inspection or monitoring for the second inspection block 28 before the subsequent processes. For example, whether the width, thickness and/or position of the second inspection block 28 or the distance between the second inspection blocks 28 meet the standard may be inspected, and thus whether the second redistribution wire 26 is offset, whether the width of the second redistribution wire 26 meets the standard, or whether the distance between the second redistribution wires 26 meets the standard may be further monitored. In addition, the formation of the through hole 30B may also be helpful to in-line inspecting or monitoring whether the top CD, the bottom CD and/or the position of the through hole 30A are offset and whether the width of the through hole 30A meets the standard in subsequent processes. The step of forming the through hole 30A and the through hole 30B of the insulating layer 30 may be similar or identical to the step of forming the through hole 18A and the through hole 18B of the insulating layer 18, so will not be described redundantly herein. In some embodiments, the through hole 30B may also correspond to the through hole 24B and expose the first inspection block 22, so as to facilitate the in-line inspection or monitoring for the relative relationship between the second inspection block 28 and the first inspection block 22 and/or the contour of the through hole 24A in subsequent processes. In some embodiments, the insulating layer 18, the insulating layer 24 and the insulating layer 30 may, for example, include polyimide (PI), polybenzoxazole (PBO), benzocyclobutene (BCB) or other suitable insulating materials, but not limited herein.

As shown in FIG. 3, after the through hole 30A is formed, a conductive pad 32 is formed in the through hole 30A to form the wire structure 16A. The conductive pad 32 may extend to the insulating layer 30 and may be used for being electrically connected to an external device, such as a circuit board. In some embodiments, the step of forming the conductive pad 32 may further include forming a third inspection block 34 in the non-device region 10B to form the inspection structure 16B, and the third inspection block 34 may be disposed adjacent to the through hole 30B. The conductive pad 32 and the third inspection block 34 may be formed by patterning the same third conductive layer C3. The method of forming the conductive pad 32 and the third inspection block 34 may include, for example, a photolithography process cooperated with an etching process or other suitable processes, but not limited herein. The first conductive layer C1, the second conductive layer C2 and the third conductive layer C3 may include, for example, copper, nickel, gold, alloys thereof or other suitable conductive materials, but not limited herein. In some embodiments, as shown in FIG. 4, the through hole 30B may overlap the second inspection block 28 in the top-view direction TD, so that the third inspection block 34 may contact the second inspection block 28 through the through hole 30B. In some embodiments, the number of the conductive pads 32 may be plural, for example. In some embodiments, the number of the third inspection blocks 34 may be plural, for example.

In some embodiments, after the conductive pad 32 is formed, a conductive ball 36 may be disposed on the conductive pad 32 to form a semi-finished package product 38. The conductive ball 36 may include, for example, solder balls or other suitable conductive materials, but not limited herein. In this embodiment, the wire structure 16A may include a part of the insulating layer 18 located in the device region 10A, a first redistribution wire 20, a part of the insulating layer 24 located in the device region 10A, a second redistribution wire 26, a part of the insulating layer 30 located in the device region 10A and a conductive pad 32, but not limited herein. In some embodiments, the number of layers of the redistribution layer 16 is not limited to that shown in FIG. 3 and FIG. 4, and may be adjusted according to practical requirements.

As shown in FIG. 3 and FIG. 4, the through hole 18B, the through hole 24B and the through hole 30B in the non-device region 10B may form the trench 16T, so that the first inspection block 22 and the second inspection block 28 may be exposed through the trench 16T. Therefore, the top CDs and the bottom CDs of the through hole 18B, the through hole 24B and/or the through hole 30B, the relative relationship between the through hole 18B, the through hole 24B and the through hole 30B, the width, the thickness and/or the position of the first inspection block 22 and/or the second inspection block 28, and the distances between the first inspection blocks 22 and/or the second inspection blocks 28 may be in-line inspected or monitored directly through the trench 16T before the subsequent cutting process. Furthermore, whether the first redistribution wire 20 and/or the second redistribution wire 26 are offset, whether the widths of the first redistribution wire 20 and/or the second redistribution wire 26 meet the standard or whether the distances between the first redistribution wires 20 and/or the second redistribution wires 26 meet the standard, and whether the relative relationship between the first redistribution wire 20 and the second redistribution wire 26 meets the standard are monitored, thereby ensuring the quality of the redistribution layer 16.

In the embodiment of FIG. 3 and FIG. 4, the inspection structure 16B may include the through hole 18B, the through hole 24B, the through hole 30B, the first inspection block 22, the second inspection block 28, the third inspection block 34, a part of the insulating layer 18, a part of the insulating layer 24 and a part of the insulating layer 30, but not limited herein. In some embodiments, the inspection block in the inspection structure 16B exposed by the trench 16T may be modified according to the practical requirements for in-line inspection or monitoring. For example, the inspection structure 16B may not have one or two of the first inspection block 22, the second inspection block 28 and the third inspection block 34. Alternatively, the trench 16T may expose the inspection block with a smaller line width for monitoring. In some embodiments, the insulating layer 24 may not have the through hole 24B in the non-device region 10B, and in such situation, the first inspection block 22 may not be in-line inspected or monitored. In some embodiments, the insulating layer 24 and the insulating layer 30 may not have the through hole 24B and the through hole 30B in the non-device region 10B. In such situation, the first inspection block 22 and the second inspection block 28 may not be in-line inspected or monitored, and only the third inspection block 34 is inspected or monitored.

In some embodiments, the inspection structure 16B may be disposed in the first non-device region 10B1, but not limited herein. In some embodiments, the inspection structure 16B may also be disposed in the second non-device region 10B2. In some embodiments, the redistribution layer 16 may include a plurality of inspection structures 16B respectively disposed in the first non-device region 10B1 and the second non-device region 10B2. In some embodiments, the inspection structure 10B may also be formed in the device region 10A.

As shown in FIG. 1 to FIG. 3, after the semi-finished package product 38 is formed, the step S14 is performed. A cutting process is performed to the semi-finished package product 38 along the cutting lines CL to remove parts of the semi-finished package product 38 in the non-device region 10B, thereby forming the package device 1. The cutting lines CL may be disposed along the edge of the device region 10A, so that the package device 1 located in the device region 10A may be separated from the parts of the semi-finished package product 38 located in the non-device region 10B. In the embodiment shown in FIG. 2 to FIG. 3, since the inspection structure 16B is disposed in the non-device region 10B, the inspection structure 16B for inspection may be separated from the package device 1 and removed after the cutting process.

In some embodiments, as shown in FIG. 2, the semi-finished package product 38 may have the same inspection structure 16B at different positions so as to in-line inspecting or monitoring the process conditions of different positions. For example, when viewed from the top-view direction TD, the semi-finished package product 38 may have the inspection structure 16B near the edge or corner, and may also have another inspection structure 16B near the center. Therefore, the correlation between the process conditions and the position of the semi-finished package product 38 may be monitored, so that the quality consistency of the manufactured package device 1 may be improved.

It should be noted that, by means of the inspection structure 16B formed by exposing at least one of the first inspection block 22 and the second inspection block 28 through the trench 16T, there is no need to perform the FIB cutting to the semi-finished package product 38, and the structures of the semi-finished package product 38 at specific positions or different positions may be directly in-line inspected or monitored. For example, the semi-finished package product 38 may be directly analyzed by the SEM. Therefore, the time for cutting the semi-finished package product 38 can be saved, especially saving the time for cutting the semi-finished package product 38 at different positions, and thus the production efficiency may be improved significantly. In addition, since there is no need to perform the FIB cutting, the inspection structure 16B for inspection will not be damaged to cause distortion by the FIB, so that the inspection results may be more accurate.

The package device and the manufacturing method thereof are not limited to the embodiments described above, and may have different embodiments. To simplify the illustration, different embodiments will use the same symbols as the first embodiment to symbolize the same elements. In order to easily compare the differences between the first embodiment and different embodiments, the following description will emphasize the differences between different embodiments, and same parts will not be described redundantly.

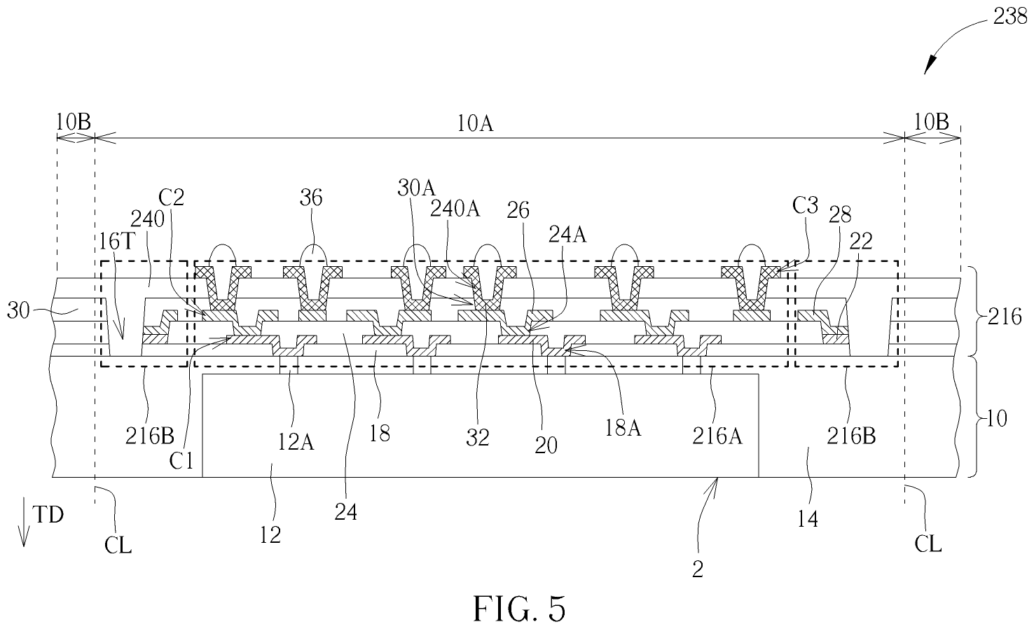

FIG. 5 schematically illustrates a cross-sectional view of a semi-finished package product before the cutting process according to a second embodiment of the present invention, wherein the structure of the semi-finished package product 238 between the cutting lines CL may be a package device 2. The difference between the semi-finished package product 238 of this embodiment and the semi-finished package product 38 shown in FIG. 3 is that the inspection structure 216B of the redistribution layer 216 is disposed in the device region 10A, so the package device 2 formed after performing the cutting process along the cutting lines CL may include the inspection structure 216B. In the embodiment of FIG. 5, the redistribution layer 216 may further include an insulating layer 240 disposed on the insulating layer 30, and the insulating layer 240 is formed between the step of forming the insulating layer 30 and the step of forming the third conductive layer C3. Furthermore, the insulating layer 240 may have a through hole 240A corresponding to the through hole 30A of the insulating layer 30, so that the conductive pad 36 may be electrically connected to the second redistribution wire 26 through the through hole 240A and the through hole 30A. In this condition, the insulating layer 240 may be disposed in the trench 16T to protect the insulating layer 18, the first inspection block 22, the insulating layer 24, the second inspection block 28 and the insulating layer 30 which are exposed by the trench 16T. In some embodiments, the inspection structure 216B may not include the third inspection block, but not limited herein. In some embodiments, the inspection structure 216B may be disposed at a side of the wire structure 216A. In some embodiments, the redistribution layer 216 may have a plurality of inspection structures 216B in the same device region 10A.

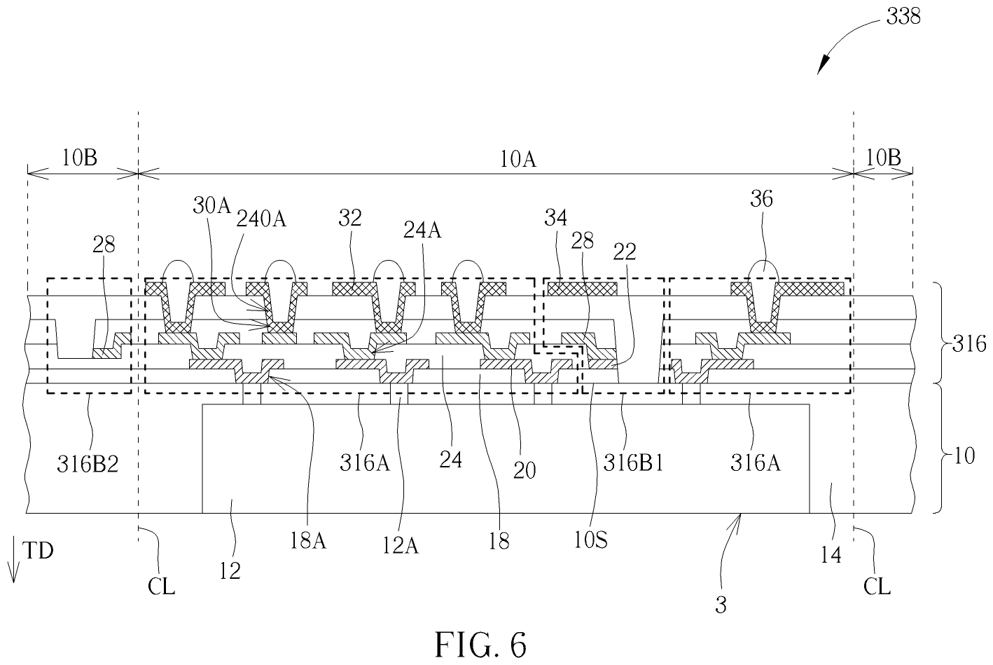

FIG. 6 schematically illustrates a cross-sectional view of a semi-finished package product before the cutting process according to a third embodiment of the present invention, wherein the structure of the semi-finished package product 338 between the cutting lines CL may be a package device 3. The difference between the semi-finished package product 338 of this embodiment and the semi-finished package product 238 shown in FIG. 5 is that the redistribution layer 316 of the inspection structure 316B1 may overlap the semiconductor chip 12 in the top-view direction TD perpendicular to the surface 10S of the substrate 10. For example, the inspection structure 316B1 may be disposed between the wire structures 316A. In some embodiment, as compared with the inspection structure 216B shown in FIG. 5, the inspection structure 316B1 may further include a third inspection block 34. In some embodiments, different inspection structures 316B1, 316B2 of the redistribution layer 316 may have different structures. For example, the inspection structure 316B2 may not include the first inspection block 22 and the third inspection block 34, but not limited herein. In some embodiments, the inspection structure 316B1 and the inspection structure 316B2 may adopt the inspection structure of any one of the embodiments described above.

From the above description, in the package device and the manufacturing method thereof of the present invention, through the inspection structure having the trench, there is no need to perform the FIB cutting to the semi-finished package product, and the structures of the semi-finished package product at specific positions or different positions may be directly in-line inspected or monitored. Therefore, the time for cutting the semi-finished package product may be saved, especially saving the time for cutting the semi-finished package product at different positions, and thus the production efficiency may be improved significantly. In addition, since there is no need to perform the FIB cutting, the inspection structure for inspection will not be damaged to cause distortion by the FIB, so that the inspection results may be more accurate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a package device, comprising:
providing a substrate, wherein the substrate has at least one device region and a non-device region; and
forming a redistribution layer on the substrate, wherein the redistribution layer comprises at least one inspection structure and at least one wire structure, the at least one wire structure is disposed in the at least one device region, a part of the at least one inspection structure and a part of the at least one wire structure are formed of a same layer, and the at least one inspection structure has a trench exposing the part of the at least one inspection structure,
wherein the redistribution layer comprises a first conductive layer and an insulating layer, the first conductive layer is disposed between the substrate and the insulating layer, the part of the at least one inspection structure comprises at least one first inspection block, and the insulating layer partially overlap the at least one first inspection block in a top-view direction of the substrate.

2. The manufacturing method of the package device according to claim 1, wherein the at least one inspection structure is formed in the non-device region.

3. The manufacturing method of the package device according to claim 1, further comprising performing a cutting process after forming the redistribution layer to remove the substrate in the non-device region and the at least one inspection structure formed in the non-device region.

4. The manufacturing method of the package device according to claim 1, wherein the at least one inspection structure is formed in the at least one device region.

5. The manufacturing method of the package device according to claim 1, wherein the substrate comprises a semiconductor chip and an encapsulant, the encapsulant surrounds the semiconductor chip, and the at least one wire structure is electrically connected to the semiconductor chip.

6. The manufacturing method of the package device according to claim 5, wherein the at least one inspection structure overlaps the semiconductor chip in the top-view direction of the substrate.

7. The manufacturing method of the package device according to claim 1, wherein the at least one wire structure comprises at least one first redistribution wire, the at least one first redistribution wire and the at least one first inspection block are formed of the first conductive layer, and the trench exposes the at least one first inspection block.

8. The manufacturing method of the package device according to claim 7, wherein the at least one wire structure further comprises at least one second redistribution wire disposed on the at least one first redistribution wire and electrically connected to the at least one first redistribution wire.

9. The manufacturing method of the package device according to claim 8, wherein the at least one inspection structure further comprises at least one second inspection block disposed on the at least one first inspection block, the at least one second inspection block and the at least one second redistribution wire are formed of a second conductive layer, and the trench exposes the at least one second inspection block.

10. The manufacturing method of the package device according to claim 7, wherein the insulating layer has a through hole overlapping the at least one first inspection block in the top-view direction of the substrate.

11. A package device, comprising:
a substrate; and
a redistribution layer disposed on the substrate, wherein the redistribution layer comprises at least one inspection structure and at least one wire structure, a part of the at least one inspection structure and a part of the at least one wire structure are formed of a same layer, and the at least one inspection structure has a trench exposing the part of the at least one inspection structure,
wherein the redistribution layer comprises a first conductive layer and an insulating layer, the first conductive layer is disposed between the substrate and the insulating layer, the part of the at least one inspection structure comprises at least one first inspection block, and the insulating layer partially overlap the at least one first inspection block in a top-view direction of the substrate.

12. The package device according to claim 11, wherein the substrate comprises a semiconductor chip and an encapsulant, the encapsulant surrounds the semiconductor chip, and the at least one wire structure is electrically connected to the semiconductor chip.

13. The package device according to claim 12, wherein the at least one inspection structure overlaps the semiconductor chip in the top-view direction of the substrate.

14. The package device according to claim 11, wherein the at least one wire structure comprises at least one first redistribution wire, the at least one first redistribution wire and the at least one first inspection block are formed of the first conductive layer, and the trench exposes the at least one first inspection block.

15. The package device according to claim 14, wherein the at least one wire structure further comprises at least one second redistribution wire disposed on the at least one first redistribution wire and electrically connected to the at least one first redistribution wire.

16. The package device according to claim 15, wherein the at least one inspection structure further comprises at least one second inspection block disposed on the at least one first inspection block, the at least one second inspection block and the at least one second redistribution wire are formed of a second conductive layer, and the trench exposes the at least one second inspection block.

17. The package device according to claim 14, wherein the insulating layer has a through hole overlapping the at least one first inspection block in the top-view direction of the substrate.

18. The package device according to claim 11, wherein the at least one inspection structure further comprises another insulating layer disposed in the trench.
